(19) United States
(12) Patent Application Publication
(10) Pub. No.: US 2010/0155227 A1
(43) Pub. Date: Jun. 24, 2010

(54) SPUTTERING APPARATUS AND FILM FORMING METHOD

(75) Inventors: Tetsuya Endo, Tokyo (JP); Einstein Noel Abarra, Tokyo (JP)

Correspondence Address: FITZPATRICK CELLA HARPER & SCINTO, 1290 Avenue of the Americas, NEW YORK, NY, 10104-3800, US

(73) Assignee: CANON ANELVA CORPORATION, Kawasaki-shi (JP)

(21) Appl. No.: 12/620,654

(22) Filed: Nov. 18, 2009

Related U.S. Application Data
(63) Continuation of application No. PCT/JP2008/073444, filed on Dec. 24, 2008.

(51) Int. Cl. C23C 14/54; C23C 14/50

(52) U.S. Cl. 204/192.12; 204/298.11; 204/298.08

(57) ABSTRACT

The present invention provides a sputtering apparatus and a film forming method that can form a high quality film in a groove having a sloping wall such as a V-groove. The sputtering apparatus of the present invention includes a rotatable cathode (102), a rotatable stage (101), and a rotatable shield plate (105). The sputtering apparatus controls rotation of at least one of the cathode (102), the stage (101), and the shield plate (105) so that sputtering particles are incident on the V-groove formed in a substrate (104) at an angle of 50° or less with respect to a normal to a sloping wall of the V-groove.

### CROSS-REFERENCES TO RELATED APPLICATIONS

This application is a continuation application of International Application No. PCT/JP2008/073444, filed on Dec. 24, 2008, the entire contents of which are incorporated by reference herein.

### TECHNICAL FIELD

The present invention relates to a sputtering apparatus and a film forming method.

### BACKGROUND ART

In order to address the recent advanced information society, it is desired to increase storage capacity of magnetic storage media such as hard disks. Increasing storage capacity of, for example, a hard disk requires a small tip of a write head.

FIG. 1 shows a fabrication method of a conventional write head.

In Step 1 in FIG. 1, a material 3 that constitutes a write head is deposited on a substrate 1 formed with a V-shaped groove (hereinafter referred to as a V-groove) 2 by vacuum deposition or sputtering. Then, in Step 2 in FIG. 1, a part 4 not required for the write head is removed from the material 3 formed on the substrate 1. Then, as shown in the right in FIG. 1, a tip 5 of the write head is formed in the V-groove 2.

However, as shown in FIG. 2A, for example, if a material is deposited on a sloping wall 6 of the V-groove 2 by normal incidence of sputtering particles 7 (vertical incidence of the sputtering particles 7 on a surface of the substrate 1 in FIG. 2A) by sputtering, the material to be formed grows in columnar shapes and columnar parts 8 are formed on the sloping wall 6 as shown in FIG. 2B. The formation of the columnar parts 8 reduces quality. Such columnar parts 8 are formed due to oblique incidence of the sputtering particles 7 on the sloping wall 6. In order to address this, for example, the substrate 1 is biased as shown in FIG. 2C. Such biasing reduces columnar growth, but in turn creates a void 9.

In order to reduce the phenomena shown in FIGS. 2B and 2C, it is necessary that the incident angle of the sputtering particles 7 is as nearly perpendicular to the sloping wall as possible. Thus, the incidence of the sputtering particles nearly perpendicular to the sloping wall 6 can reduce columnar growth of a film. Patent Document 1 discloses a configuration for incidence of sputtering particles at an angle nearly perpendicular to a V-groove.

FIG. 3 shows a configuration of a sputtering apparatus disclosed in Patent Document 1.

In FIG. 3, a substrate 12 formed with a V-groove 13 is placed on a substrate holder 11 having a sloping substrate placing surface. Above the substrate holder 11, a target 14 is provided having a magnet 16 on a surface opposite to a target surface 14a. Further, a target 15 having a magnet 17 with a polarity different from that of the magnet 16 on a surface opposite to a target surface 15a is provided in an upper position than the target 14 by predetermined space. Such a configuration produces magnetic field 18 for containing plasma.

In the sputtering apparatus disclosed in Patent Document 1, in the configuration in FIG. 3, sputtering particles from the target 15 contribute to deposition on the sloping wall 13a of the V-groove, and sputtering particles from the target 14 contribute to deposition on the sloping wall 13b. At this time, the positional relationship between the substrate 12 and the targets 14 and 15 is adjusted, and thus an incident angle of the sputtering particles incident on the sloping wall 13a from the target 15 can be nearly perpendicular to the sloping wall 13a, and an incident angle of the sputtering particles incident on the sloping wall 13b from the target 14 can be nearly perpendicular to the sloping wall 13b.

Patent Document 1: Japanese Patent Application Laid-Open No. H10-330930

### DISCLOSURE OF THE INVENTION

The sputtering disclosed in Patent Document 1 can reduce columnar growth on the sloping walls 13a and 13b of the V-groove 13, and obtain sufficient film quality at the time of filing of the application as to Patent Document 1. However, with requests for write heads according to recent developments of the advanced information society, it is desired to further increase quality of a film formed in a V-groove.

Specifically, in Patent Document 1, positions of the substrate 12 and the targets 14 and 15 are fixed, and in some positions in a tilt direction of the tilted substrate 12, variations occur in incident angle of the sputtering particles with respect to the V-groove 13. This may cause variations in quality between a film formed in a V-groove on a lower side (a left side in FIG. 3) in a sloping direction of the substrate holder 11 and a film formed in a V-groove on an upper side (a right side in FIG. 3) in the sloping direction.

The present invention is achieved in view of such circumstances, and has an object to provide a sputtering apparatus and a film forming method that can form a film in a groove having a sloping wall such as a V-groove with high quality.

A first aspect of the present invention provides a sputtering apparatus including: a cathode having a sputtering target support surface rotatable about a first rotating shaft; a stage having a substrate support surface rotatable about a second rotating shaft arranged in parallel with the first rotating shaft; and a shield plate provided between the sputtering support surface and the substrate support surface and rotatable about the first rotating shaft or the second rotating shaft, wherein when a substrate with at least one V-groove is disposed on the substrate support surface during sputtering, rotation of at least one of the sputtering target support surface, the substrate support surface, and the shield plate is controlled so that sputtering particles incident at an angle formed 50° or less with respect to a normal to a sloping wall of the V-groove are incident on the V-groove formed in the disposed substrate.

A second aspect of the present invention provides a sputtering apparatus including: a cathode having a sputtering target support surface rotatable about a first rotating shaft; a stage having a substrate support surface rotatable about a second rotating shaft arranged in parallel with the first rotating shaft; and a shield plate provided between the sputtering support surface and the substrate support surface and rotatable about the first rotating shaft or the second rotating shaft, wherein the shield plate has a slit-shaped opening portion through which sputtering particles can pass, and the opening portion has a larger width in a direction perpendicular to a rotational direction of the shield plate than the width in the rotational direction.

A third aspect of the present invention provides a sputtering apparatus including: a cathode having a sputtering target support surface rotatable about a first rotating shaft; a stage having a substrate support surface rotatable about a second rotating shaft arranged in parallel with the first rotating shaft; and a shield plate provided between the sputtering support surface and the substrate support surface and rotatable about the first rotating shaft or the second rotating shaft, wherein when a substrate with at least one V-groove is placed on the substrate support surface during sputtering, rotation of at least one of the sputtering target support surface, the substrate support surface, and the shield plate is controlled so that the percentage of sputtering particles incident at an angle of 50° or less with respect to a normal to a sloping wall of the V-groove formed in the placed substrate is highest.

A fourth aspect of the present invention provides a film forming method using a sputtering apparatus including: a cathode having a sputtering target support surface rotatable about a first rotating shaft; a stage having a substrate support surface rotatable about a second rotating shaft arranged in parallel with the first rotating shaft; and a shield plate provided between the sputtering support surface and the substrate support surface and rotatable about the first rotating shaft or the second rotating shaft, wherein when a substrate with at least one V-groove is placed on the substrate support surface during sputtering, at least one of the sputtering target support surface, the substrate support surface, and the shield plate is rotated so that sputtering particles incident at an angle formed 50° or less with respect to a normal to a sloping wall of the V-groove are incident on the V-groove formed in the substrate.

### BRIEF DESCRIPTION OF THE DRAWING

FIG. 1 shows a conventional method of fabricating a pole tip of a write head;

FIG. 2A shows sputtering particles being incident on a substrate with a V-groove normal to the substrate in a conventional example;

FIG. 2B shows columnar parts being formed in the V-groove by sputtering in FIG. 2A;

FIG. 2C shows a void being formed in the V-groove by the sputtering in FIG. 2A;

FIG. 3 shows a configuration of a conventional sputtering apparatus;

FIG. 4 shows an example of a sputtering apparatus according to an embodiment of the present invention;

FIG. 5 is a top view of a shield plate according to one embodiment of the present invention;

FIG. 6 is a sectional view of a V-groove formed in a substrate according to one embodiment of the present invention;

FIG. 7 illustrates film forming operation using the sputtering apparatus according to one embodiment of the present invention;

FIG. 8 shows a relationship between an incident angle with respect to a sloping surface of the V-groove and saturation flux density according to one embodiment of the present invention; and

FIG. 9 illustrates film forming operation using a sputtering apparatus according to one embodiment of the present invention.

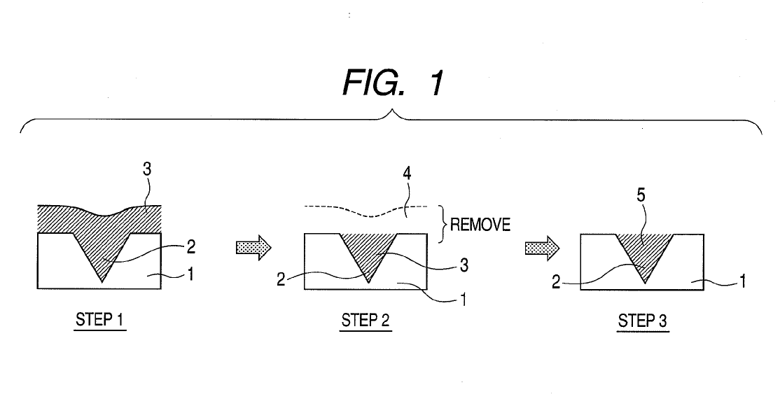

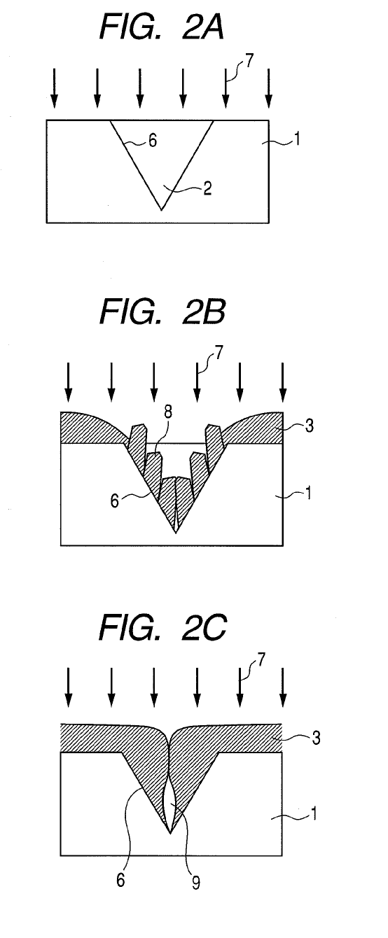

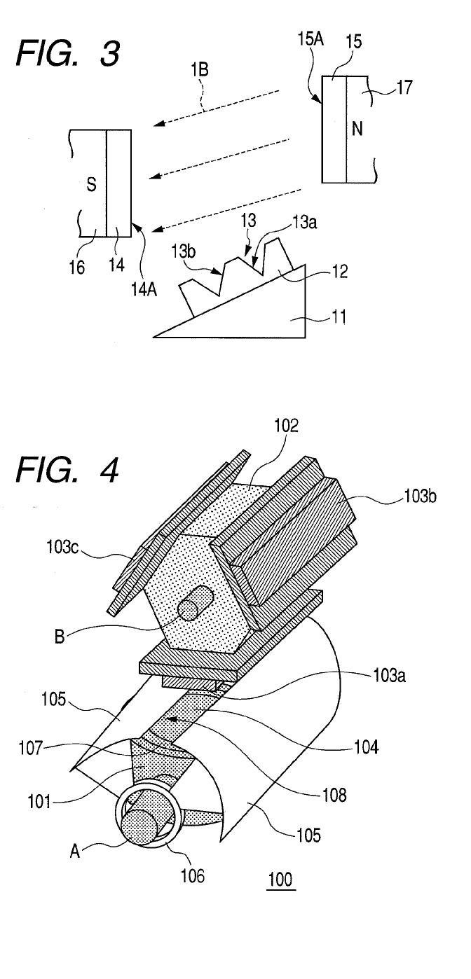

### BEST MODES FOR CARRYING OUT THE INVENTION

Now, embodiments of the present invention will be described in detail with reference to the drawings. In the drawings, components having the same functions are denoted by the same reference numerals, and repeated descriptions thereof will be omitted.

### First Embodiment

FIG. 4 shows an example of a sputtering apparatus according to this embodiment. The sputtering apparatus 100 includes a stage 101 on which a substrate 104 is placed, a cathode 102 supporting a target 103, and a shield plate 105 having a slit-shaped opening portion 108. The stage 101 and the cathode 102 include a rotating shaft A and a rotating shaft B, respectively, and at least one of the stage 101 and the cathode 102 is rotated about the rotating shaft A and the rotating shaft B at an arbitrary angle. For example, at least one of the stage 101 and the cathode 102 can be rotated by rotating means such as a motor, and the rotating means can be controlled by a control apparatus. The rotating shaft A and the rotating shaft B are arranged in parallel with each other, and the target 103 is supported by the cathode 102 in parallel with the rotating shaft B.

The target 103 supported by the cathode 102 rotatable about the rotating shaft B at an arbitrary angle can deposit sputtering particles on the substrate 104 by causing ions in plasma to collide with a surface of the target 103 in both stationary and rotating conditions.

The substrate 104 on which a film is formed by targets 103a to 103c is placed on the stage 101 rotatable about the rotating shaft A at an arbitrary angle. A V-groove (not shown) is formed in the substrate 104. The stage 101 includes a substrate placing table 107, and the substrate 104 can be provided on the substrate placing table 107. The substrate table 107 of the stage 101 is rotatable about a rotating shaft (not shown) perpendicular to the rotating shaft A and passing through the center of the substrate 104, and can rotate the substrate 104 about this rotating shaft. The substrate table 107 can be rotated by rotating means such as a motor, and the rotating means can be controlled by the control apparatus.

Further, a shield plate 105 having a slit-shaped opening portion 108 through which sputtering particles can pass is provided between the target and the stage 101, and the shield plate 105 includes means for being rotated about the rotating shaft A at an arbitrary angle and has functions for fine adjustment of the thickness distribution of a deposited film and control of the incident angle of the sputtered particles. The shield plate 105 can be rotated about the rotating shaft A independent of the cathode 102 or the stage 101 by the control apparatus properly controlling the shield plate rotating means 106.

FIG. 4 shows the shield plate 105 being rotated about the rotating shaft A, but the shield plate 105 may be rotated about the rotating shaft B by providing the shield plate rotating means 106 in the cathode 102 or the like.

A plurality of targets 103 are desirably supported by the cathode 102. The reason for this will be described below. Many of magnetic materials such as Fe—Co alloy used for a write head have high saturation flux density, and the limit of thickness of a target material used in a sputtering process is 4 to 5 mm. This prevents an increase in the number of processes for film forming. Thus, a plurality of identical target materials are provided to allow continuous processes without replacement of targets or the like. In the example in FIG. 4, the plurality of targets 103a, 103b and 103c are provided and can be separately used for the above described application and different applications. The rotating shaft A and the rotating shaft B are arranged in parallel with each other, and the targets 103a, 103b and 103c are supported by the cathode 102 in parallel with the rotating shaft B. The targets 103a, 103b and 103c rotatable about the rotating shaft B deposit sputtering particles on the substrate 104 by causing ions in plasma to collide with the surface of the target 103.

It is to be understood that the number of the targets may be one or more.

In this embodiment, as in the above described configuration, in film forming by sputtering, the slit-shaped shield plate 105 is provided between the substrate and the target, and the shield plate 105 is rotated during film forming so that sputtering particles are incident on the V-groove formed in the substrate 104 from a target of interest in an angle range as nearly perpendicular to a sloping wall of the V-groove (a sloping surface of the V-groove) as possible (an angle range where an angle with respect to a normal to the sloping wall is minimized). Such control allows the sputtering particles incident on the sloping wall of the V-groove in a predetermined angle range to contribute to film forming. This allows film forming (deposition) while reducing sloping components with respect to the sloping wall of the sputtering particles incident on the sloping wall of the V-groove. This can reduce columnar growth or void formation in the V-groove after film forming.

In this embodiment, an example where the cathode 102 is fixed and the stage 101 and the shield plate 105 are rotated during film forming will be described.

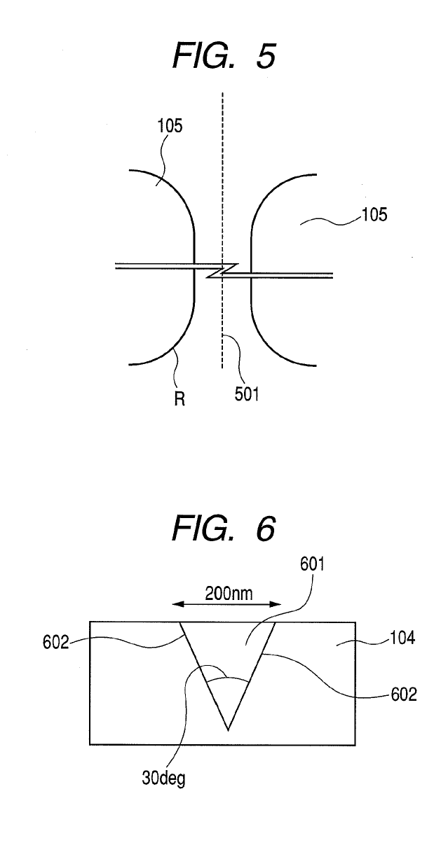

FIG. 5 is a top view of the shield plate 105 according to this embodiment. The shield plate 105 may be formed by forming an opening portion 108 in one shield plate, or spacing two shield plates apart a predetermined distance. Specifically, it is important in this embodiment that the shield plate 105 has the opening portion 108 for narrowing the incident angle of sputtering particles heading toward the substrate from the target to a predetermined angle range. The opening portion 108 is thus formed, and at each moment during film forming, sputtering particles at an incident angle that are not to be incident on the V-groove formed in the substrate 104 can be blocked by the shield plate 105, and sputtering particles incident at a proper incident angle can be incident on the V-groove through the opening portion 108.

In the specification, “incident angle” refers to an angle formed between a normal to a surface on which the sputtering particles are incident (a surface of the sloping wall of the V-groove or the substrate surface) and an incident direction of the incident sputtering particles.

As shown in FIG. 5, the opening portion 108 has a larger width in a direction (a vertical direction in FIG. 5) perpendicular to a rotational direction (a horizontal direction in FIG. 5) of the shield plate 105 than a width in the rotational direction. Also, an edge in the direction perpendicular to the rotational direction of the shield plate 105 has a radius of curvature R.

FIG. 6 is a sectional view of the V-groove formed in the substrate 104. As shown in FIG. 6, in the substrate 104, a V-groove 601 having a sloping wall 602 is formed as a pattern shape on a substrate on which a film is formed. The V-groove 601 is formed in the substrate 104 so that a longitudinal direction of the groove matches the direction perpendicular to the rotational direction (the vertical direction in FIG. 5). Thus, a forming direction of the sloping surface of the V-groove 601 matches a moving direction of the shield plate 105. In this embodiment, it is important to minimize an incident angle with respect to the sloping wall (the sloping surface of the V-groove) 602 at each moment during film forming by rotation control of the shield plate 105. In order to achieve this, in this embodiment, the incident angle of the sputtering particles incident on the sloping wall 602 is controlled by a relative positional relationship between the opening portion 108 of the shield plate 105, the target, and the substrate 104, and the forming direction of the sloping surface of the V-groove is matched to the moving direction of the shield plate 105 so that technical advantage of the shield plate 105 blocking sputtering particles at an unnecessary incident angle from the target is applied to the sloping wall 602 of the V-groove. In this embodiment, an example where a V-groove opening width of 200 nm and an opening angle of 30° is described, but it is to be understood that the opening width and the opening angle of the V-groove are not limited to the above described values in the present invention. In the specification, “opening angle” refers to an angle formed between one sloping surface and the other sloping surface of the V-groove.

Operation of the sputtering apparatus in this embodiment will be described next.

In this embodiment, the target 103a is a target of interest. The distance between the target 103a and the substrate 104 when the target 103a is parallel to the substrate 104 is 100 nm, the size of the target 103a is 450 mm×130 mm, and the diameter of the substrate 104 is 200 mm. At least one V-groove is formed in the substrate 104 as shown in FIG. 6. The width in the rotational direction of the opening portion 108 of the shield plate 105 (width in the horizontal direction in FIG. 5) is 25 mm, the width of the shield plate 105 (width in the vertical direction in FIG. 5) is 450 mm, and the radius of curvature R of the shield plate 105 is 100 mm. The rotation radius of the shield plate 105 (distance between the center of the rotating shaft A and the shield plate 105) is 330 mm, and the rotation radius of the target (distance between the center of the rotating shaft B and the target) is 160 mm.

As discharge conditions, sputtering power is 4000 W (DC), bias is 50 W/13.56 MHz, gas pressure is 0.05 Pa, and a material of the target 103a is Fe—Co alloy.

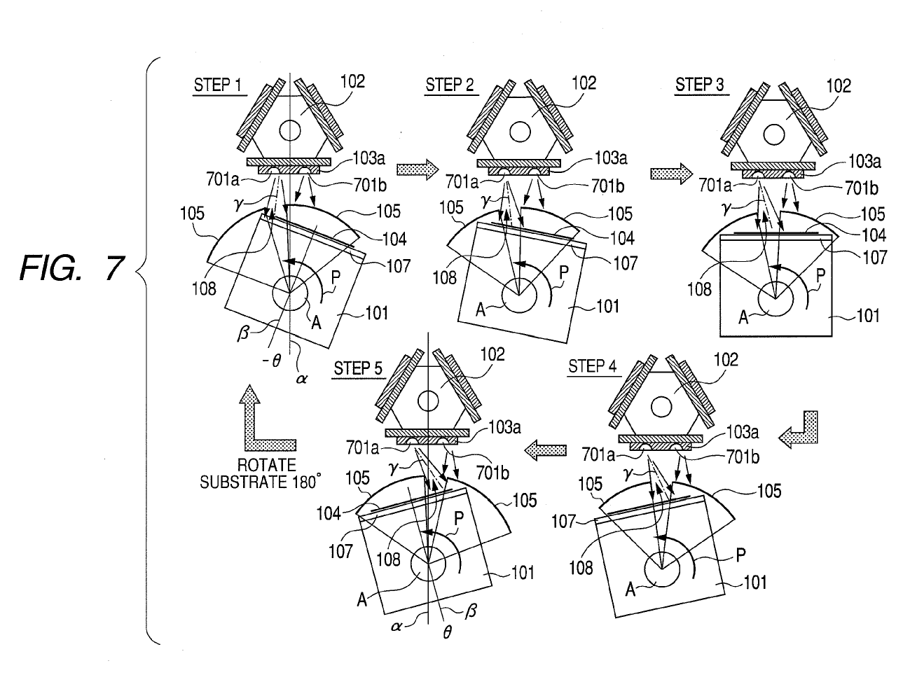

FIG. 7 illustrates film forming operation using the sputtering apparatus according to this embodiment.

In FIG. 7, a rectangular erosion track (erosion portion) 701 is formed in the target 103a. The erosion track is formed in the targets 103b and 103c in some cases.

In this embodiment, the incident angle of sputtering particles generated from one (hereinafter referred to as “erosion side to be noted”) of an upstream region (region 701a) and a downstream region (a region 701b) of the erosion track 701 in a rotational direction P of the stage 101 falls within a predetermined range. Specifically, in this embodiment, the opening portion 108 is located so that at least sputtering particles incident on the substrate 104 perpendicularly or at an angle (for example, 0° to)5° nearly perpendicular to the substrate 104 among sputtering particles generated from a region that is not the erosion side to be noted (hereinafter referred to as “erosion side not to be noted”) of the erosion track are blocked by the shield plate 105 as much as possible, and sputtering particles incident at a predetermined incidentangle are incident on the substrate 104 among sputtering articles generated from the erosion side to be noted.

In FIG. 7, a reference line a connects the center of the rotating shaft A and the center of the rotating shaft B. A centerline βconnects the center of the rotating shaft A and the center of rotation of the substrate placing table 107. Further, a line γ connects a predetermined region of the erosion side to be noted (for example, a point with the deepest region in the erosion track) and an arbitrary point on a centerline (reference numeral 501 in FIG. 5) of the opening portion 108 in the longitudinal direction of the opening portion 108 (for example, a midpoint in the longitudinal direction of the opening portion 108 on the centerline 501). The line γ may connect an arbitrary point in a region surrounded by the erosion track 701 (for example, a central point) and an arbitrary point on the centerline 501 (for example, a midpoint in the longitudinal direction of the opening portion 108 on the centerline 501). In this embodiment, the position of the line γ is not essential but using the provided line γ as a reference for control is important, and thus the line γ may be provided with reference to any position.

In this embodiment, the cathode 102 is fixed, the stage 101 is rotated about the rotating shaft A in the arrow direction P, the shield plate 105 is rotated as appropriate, and operations from Steps 1 to 5 in FIG. 7 are performed. After Steps 1 to 5 in FIG. 7 are finished and a film is once formed on a predetermined region on the substrate 104, the substrate 104 is rotated 180°, and Steps 1 to 5 in FIG. 7 are performed again.

Specifically, in each step in FIG. 7, the shield plate 105 and the stage 101 are independently rotated so that the angle formed between a normal to the substrate 104 and the line γ falls within a predetermined angle.

For example, when a main incident angle of sputtering particles with respect to the substrate 104 is to be 30° (the percentage of sputtering particles at an incident angle of about 30° is to be highest), rotation of the shield plate 105 and the stage 101 is controlled so that the angle formed between the substrate 104 (normal to the substrate support surface of the stage 101) and the line γ is about 30° that is the incident angle for the highest percentage of the sputtering particles.

At this time, at the start of sputtering film forming (Step 1 in FIG. 7), the stage 101 is located so that an angle θ formed between the reference line α and the centerline β is −25°. Specifically, at the start of sputtering film forming (Step 1 in FIG. 7), the opening portion 108 of the shield plate 105 and the substrate 104 are located so that the upstream region (the region 701a) in the rotational direction (the rotational direction of the stage 101) of the substrate 104 is the erosion side to be noted.

When the percentage of sputtering particles incident on the substrate at the predetermined incident angle (for example, the above described main incident angle) is to be highest, optimum positions of the shield plate, the cathode, and the stage may be calculated by simulation to control rotations of the shield plate, the cathode, and the stage according to simulation results.

During sputtering film forming, the stage 101 is rotated about the rotating shaft A in the arrow direction P, and Steps 2 to 5 in FIG. 7 are performed. In Step 5 in FIG. 7 at the finish of sputtering film forming, the stage 101 is rotated so that the angle θ is 7°. In the specification, the state where the centerline β is tilted to the left in FIG. 7 from the reference line α is indicated by “+angle” and the state where the centerline β is tilted to the right is indicated by “−angle”.

Specifically, rotation of the shield plate 105 and the stage 101 is controlled so that the angle formed between the normal to the substrate 104 and the line γ is 30° at each moment during sputtering film forming (for example, Steps 1 to 5 in FIG. 7). Thus, the sputtering particles at the incident angle of 30° are incident on the substrate 104 at the highest percentage. This can reduce the incident angle of the sputtering particles incident on the V-groove formed in the substrate 104, and provide a uniform magnetic film on the V-groove. Even with such control, there may be sputtering particles incident on the substrate 104 perpendicular or at an incident angle nearly perpendicular to the substrate 104 (sputtering particles incident on the sloping wall of the V-groove at a large angle). However, in this embodiment, rotation of the shield plate 105 and the stage 101 is controlled so that the percentage of the sputtering particles incident at the incident angle that allows a magnetic film to be satisfactorily formed in the V-groove is highest, thereby reducing sputtering particles incident on the substrate 104 perpendicular or at an incident angle nearly perpendicular to the substrate 104 and reducing contribution of these sputtering particles to film forming.

As such, rotation of the stage 101 and the shield plate 105 is controlled so that the percentage of the sputtering particles incident at the predetermined incident angle is highest, and a region on which the sputtering particles are deposited is gradually moved from an upstream end (left end in FIG. 7) in the rotational direction of the substrate 104 to a downstream end (right end in FIG. 7) in the rotational direction, and Step 1 (at the start of sputtering film forming) to Step 5 (at the finish of sputtering film forming) in FIG. 7 are performed.

In this embodiment, it is essential that the sputtering particles are incident on the sloping surface of the V-groove so as to reduce columnar growth and increase atomic density in the film formed in the V-groove by sputtering. For this purpose, the sputtering particles need to be incident on the sloping wall of the V-groove (the sloping surface of the V-groove) within an appropriate incident angle range.

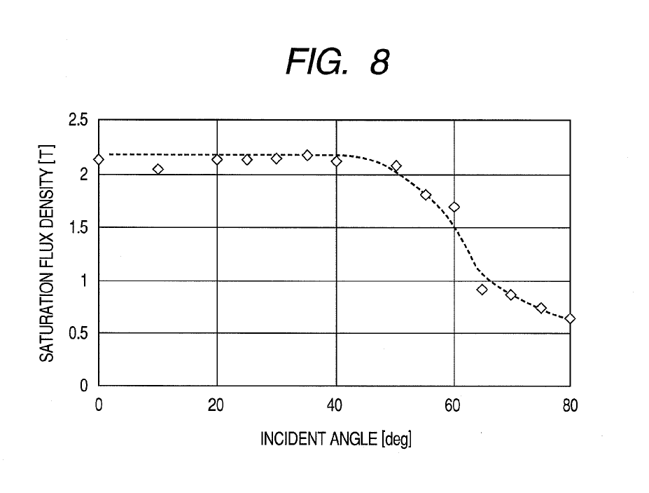

FIG. 8 shows a relationship between the incident angle with respect to the sloping surface of the V-groove and saturation flux density according to this embodiment. As shown in FIG. 8, when the incident angle with respect to the sloping surface of the V-groove is larger than 50°, the saturation flux density is reduced. Specifically, the atomic density in the film formed in the V-groove is reduced. This occurs due to an increase in the incident angle with respect to the sloping surface of the V-groove to cause much columnar growth.

Thus, in this embodiment, at least one of the cathode, the stage, and the shield plate is preferably independently controlled so that the incident angle of the sputtering particles with respect to the sloping surface of the V-groove is 50° or less. Thus, in this embodiment, the incident angle with respect to the substrate is set to a predetermined incident angle so that the incident angle of the sputtering particles with respect to the sloping surface of the V-groove is 50° or less. Therefore, the predetermined incident angle (the incident angle with respect to the substrate) is an angle at which the sputtering particles are incident on the sloping surface of the V-groove at the incident angle of 50° or less.

At any opening angle of the V-groove in which a film is to be formed, a range of incident angles with respect to the substrate at which the incident angle of the sputtering particles with respect to the sloping surface of the V-groove is 50° or less can be geometrically calculated according to the opening angle. Thus, for example, when the percentage of the sputtering particles incident at a predetermined angle within the range at which the incident angle of the sputtering particles with respect to the sloping surface of the V-groove is 50° or less is to be highest, an incident angle with respect to the substrate corresponding to the predetermined angle can be geometrically calculated. Then, control conditions may be calculated by simulation or the like so that the sputtering particles incident on the substrate at the incident angle thus calculated are at the highest percentage.

In this embodiment, when Step 5 in FIG. 7 is finished, the substrate placing table 107 is rotated to rotate 180° the substrate 104. Then, the shield plate 105 and the stage 101 are rotated so as to obtain the positional relationship in Step 1 in FIG. 7. Specifically, a region on which a film is last formed in the previous sputtering film forming is used as a start region of the current sputtering film forming.

As such, the substrate once subjected to the sputtering film forming is rotated 180° to again perform film forming on the substrate formed with the film, thereby improving thickness distribution. Specifically, in this embodiment, the substrate is rotated 180° to perform sputtering, on a film formed by sputtering from one end to the other end of the substrate under a certain condition, from the other end to one end under the certain condition. Thus, the substrate 104 is subjected to the sputtering under the same condition in film forming from one end to the other end of the substrate (first film forming) and film forming from the other end to one end (second film forming). Thus, in symmetrical positions on the substrate 104 in the rotational direction (the moving direction of the substrate 104) of the stage 101, a film formed in the first film forming and a film formed in the second film forming under the same condition as the first film forming are deposited. Thus, influences of the first film forming and the second film forming can be cancelled on the entire surface of the substrate 104 to provide uniform thickness distribution.

Also, for example, when the main incident angle of the sputtering particles with respect to the substrate 104 is to be 15°, rotation of the shield plate 105 and the stage 101 is controlled so that the angle formed between the substrate 104 and the line γ is about 15° that is the incident angle for the highest percentage of the sputtering particles. At this time, in Step 1 in FIG. 7, the angle θ is set to −23°, and in Step 5, the angle θ is set to 9°. Then, along with Steps 1 to 5 in FIG. 7, the stage 101 is rotated so that the angle θ varies between −23° to 9°, and rotation of the shield plate 105 and the stage 101 is controlled so that the angle formed between the normal to the substrate 104 and the line γ is maintained at 15°. Specifically, the rotation of the shield plate 105 and the stage 101 is controlled so that the incident angle of the sputtering particles with respect to the sloping wall of the V-groove formed in the substrate 104 is 50° or less.

Further, for example, when the main incident angle of the sputtering particles with respect to the substrate 104 is to be 5°, rotation of the shield plate 105 and the stage 101 is controlled so that the angle formed between the substrate 104 and the line γ is about 5°, that is, the incident angle for the highest percentage of the sputtering particles. At this time, in Step 1 in FIG. 7, the angle θ is set to −20°, and in Step 5, the angle θ is set to 13°. Then, along with Steps 1 to 5 in FIG. 7, the stage 101 is rotated so that the angle θ varies between −20 to −13°, and rotation of the shield plate 105 and the stage 101 is controlled so that the angle formed between the normal to the substrate 104 and the line γ is maintained at 5°. Specifically, rotation of the shield plate 105 and the stage 101 is controlled so that the incident angle of the sputtering particles with respect to the sloping wall of the V-groove formed in the substrate 104 is 50° or less.

The case where the target formed with the erosion track is used is described above, but this embodiment may be applied to the case where a target without an erosion track such as a new target is used. For example, when a cathode is used having a first magnet with one polarity and a second rectangular magnet with the other polarity arranged into a rectangular shape to surround the first magnet, an assembly of regions where a vertical component of a magnetic field produced between the first magnet and the second rectangular magnet with respect to a target support surface of the cathode is zero in the target defines the region where an erosion track forms.

In the embodiment, an annular magnet may be used instead of the second rectangular magnet. In this embodiment, it is important that the first magnet is surrounded by the magnet with the other polarity to form a loop, and the loop may have any shape.

### Second Embodiment

In the first embodiment, the example where the cathode is fixed is described. In this embodiment, an example in which the cathode is also rotated together with the stage and the shield plate will be described.

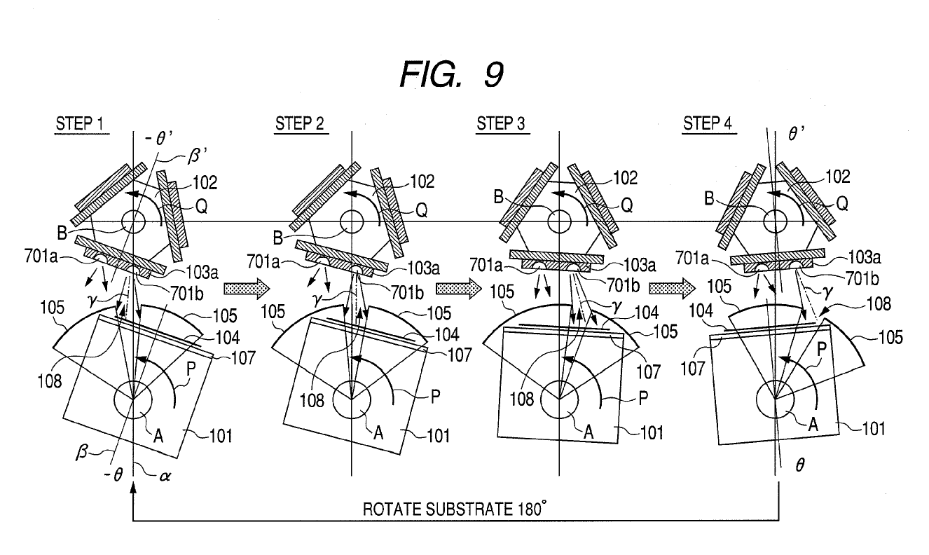

FIG. 9 illustrates film forming operation using a sputtering apparatus according to this embodiment. In this embodiment, the same operation as in the first embodiment is performed other than the cathode 102 being rotated about the rotating shaft B in the same direction as the stage 101. Specifically, in each step in FIG. 9, the shield plate 105, the stage 101, and the cathode 102 are independently rotated so that the angle formed between the normal to the substrate 104 and the line γ falls within a predetermined angle range. At this time, in this embodiment, rotation of the cathode 102 and the stage 101 is controlled so that a target support surface of the cathode 102 on which a target of interest is placed is parallel to a substrate support surface of the stage 101 during sputtering film forming.

Then, in this embodiment, when Steps 1 to 4 in FIG. 9 are finished, the substrate placing table 107 is rotated 180°, and Steps 1 to 4 are performed again.

For example, when a main incident angle of the sputtering particles with respect to the substrate 104 is to be 15°, rotation of the shield plate 105, the stage 101, and the cathode 102 is controlled so that the angle formed between the substrate 104 and the line γ is about 15°, that is, the incident angle for the highest percentage of the sputtering particles. Specifically, rotation of the shield plate 105 and the stage 101 is controlled so that the incident angle of the sputtering particles with respect to the sloping wall of the V-groove formed in the substrate 104 is 50° or less.

At the start of sputtering film forming (Step 1 in FIG. 9), the stage 101 and the cathode 102 are located so that an angle θ formed between a reference line α and a centerline β and an angle θ′ formed between a reference line α′ and a centerline β′ are −16°. Thus, the substrate support surface of the stage 101 is parallel to the cathode support surface on which the target 103a for sputtering is placed. The opening portion 108 of the shield plate 105 is located so that the region 701b of the erosion truck 701 is an erosion side to be noted.

The centerline β′ connects the center of the rotating shaft B and the center of the target 103a of interest.

Then, during sputtering film forming, the stage 101 is rotated about the rotating shaft A in the arrow direction P, the cathode 102 is rotated about the rotating shaft B in an arrow direction Q, and Steps 2 to 4 in FIG. 9 are performed. In each step, the cathode 102 and the stage 101 are rotated so that the target 103a is parallel to the substrate 104. In Step 4 in FIG. 9 at the finish of sputtering film forming, the cathode 102 and the stage 101 are rotated so that the angles θ and θ′ are each 8°.

In the embodiment, the surface of the target 103a for sputtering is parallel to the substrate 104 during sputtering film forming, and thus a relative positional relationship between the target 103a and the substrate 104 does not change at each moment of sputtering though the cathode 102 and the stage 101 are rotated. This can reduce variations in the incident angle of the sputtering particles with respect to the substrate 104.

In this embodiment, the cathode 102 is also rotated during sputtering film forming, and thus the target 103a can be parallel to the substrate 104 at any moment during sputtering film forming for reducing variations in the incident angle.

As such, according to the embodiment, the target 103a of interest is parallel to the substrate 104 during sputtering film forming, thereby allowing further matching of the incident angle with respect to the substrate 104. Also, when Step 4 in FIG. 9 is finished, the substrate 104 is rotated, and Steps 1 to 4 in FIG. 9 are further performed, thereby improving thickness distribution.

### Third Embodiment

The stage 101 having the substrate support surface may include an electrostatic adhesion mechanism. A conventionally general method is to mechanically secure the edges of a substrate with an annular component. The stage itself is rotated and tilted such that substrates may fall if there are no provisions for clamping. Moreover, in order to seal a substrate cooling gas, an O-ring or the like is inserted between the stage and the substrate to prevent leakage of the cooling gas.

In this embodiment, the electrostatic adhesion mechanism is provided to allow the substrate 104 to be secured on the substrate placing table 107 without an O-ring or the like. This can prevent warp of the substrate on the O-ring and fall of the substrate. Further, in the securing method with the annular component, the substrate surface is in contact with the annular component and thus it is difficult to bias the substrate in terms of contamination, but the electrostatic adhesion mechanism allows only the substrate to be biased.

A bias power supply may be connected to the stage 101 to apply a bias voltage (DC bias or high frequency bias) to the stage 101. The bias voltage is thus applied to allow sputtering particles to be deposited more closely.

1. A sputtering apparatus comprising:
a cathode having a sputtering target support surface rotatable about a first rotating shaft;
a stage having a substrate support surface rotatable about a second rotating shaft arranged in parallel with said first rotating shaft; and
a shield plate provided between said sputtering support surface and said substrate support surface and rotatable about said first rotating shaft or said second rotating shaft,
wherein when a substrate with at least one V-groove is placed on said substrate support surface during sputtering, rotation of at least one of said sputtering target support surface, said substrate support surface, and said shield plate is controlled so that a positional relationship between said sputtering target support surface, said substrate support surface, and said shield plate during said sputtering is a positional relationship in which sputtering particles incident at an angle formed of 50° or less with respect to a normal to a sloping wall of the V-groove are incident on said V-groove formed in said placed substrate.

2. The sputtering apparatus according to claim 1, wherein during said sputtering, said sputtering target support surface is fixed and said shield plate and said substrate support surface are rotated.

3. The sputtering apparatus according to claim 2, wherein said stage includes a substrate placing table rotatable about a third rotating shaft perpendicular to said second rotating shaft, and
said substrate placing table is rotated 180° about said third rotating shaft when film forming of a region on which a film is to be formed on said substrate is finished during said sputtering.

4. The sputtering apparatus according to claim 1, wherein said sputtering target support surface and said substrate support surface are rotated in the same direction and in parallel with each other during said sputtering.

5. The sputtering apparatus according to claim 4, wherein said stage includes a substrate placing table rotatable about a third rotating shaft perpendicular to said second rotating shaft, and
said substrate placing table is rotated 180° about said third rotating shaft when film forming of a region on which a film is to be formed on said substrate is finished during said sputtering.

6. The sputtering apparatus according to claim 1, further comprising a control apparatus for controlling rotation of at least one of said sputtering target support surface, said substrate support surface, and the shield plate.

7. The sputtering apparatus according to claim 1, wherein said cathode includes a plurality of sputtering target support surfaces, and said plurality of sputtering target support surfaces are arranged around said cathode.

8. The sputtering apparatus according to claim 1, wherein said stage includes an electrostatic adhesion mechanism.

9. The sputtering apparatus according to claim 1, wherein said stage is electrically connected to a bias power supply that can apply a bias voltage to said stage.

10. A sputtering apparatus comprising:
a cathode having a sputtering target support surface rotatable about a first rotating shaft;
a stage having a substrate support surface rotatable about a second rotating shaft arranged in parallel with said first rotating shaft; and
a shield plate provided between said sputtering support surface and said substrate support surface and rotatable about said first rotating shaft or said second rotating shaft,
wherein said shield plate has a slit-shaped opening portion through which sputtering particles can pass,
said opening portion has a larger width in a direction perpendicular to a rotational direction of said shield plate than a width in said rotational direction, and
when a substrate with at least one V-groove is placed on said substrate support surface during sputtering, rotation of at least one of said sputtering target support surface, said substrate support surface, and said shield plate is controlled so that a positional relationship between said sputtering target support surface, said substrate support surface, and said shield plate during said sputtering is a positional relationship in which an incident angle of sputtering particles incident on said V-groove through said opening portion is 50° or less, said incident angle being formed between a normal to a sloping wall of said V-groove and an incident direction of the sputtering particles with respect to said V-groove.

11. The sputtering apparatus according to claim 10, wherein the width in said rotational direction of said opening portion is larger than 5 mm and smaller than 40 mm.

12. A sputtering apparatus comprising:
a cathode having a sputtering target support surface rotatable about a first rotating shaft;
a stage having a substrate support surface rotatable about a second rotating shaft arranged in parallel with said first rotating shaft; and
a shield plate provided between said sputtering support surface and said substrate support surface and rotatable about said first rotating shaft or said second rotating shaft,
wherein when a substrate with at least one V-groove is placed on said substrate support surface during sputtering, rotation of at least one of said sputtering target support surface, said substrate support surface, and said shield plate is controlled so that a positional relationship between said sputtering target support surface, said substrate support surface, and said shield plate during said sputtering is a positional relationship in which the percentage of sputtering particles incident at an angle of 50° or less with respect to a normal to a sloping wall of the V-groove formed in said placed substrate is highest.

13. A film forming method using a sputtering apparatus comprising:
a cathode having a sputtering target support surface rotatable about a first rotating shaft;
a stage having a substrate support surface rotatable about a second rotating shaft arranged in parallel with said first rotating shaft; and
a shield plate provided between said sputtering support surface and said substrate support surface and rotatable about said first rotating shaft or said second rotating shaft,
wherein when a substrate with at least one V-groove is placed on said substrate support surface during sputtering, at least one of said sputtering target support surface, said substrate support surface, and said shield plate is rotated so that a positional relationship between said sputtering target support surface, said substrate support surface, and said shield plate during said sputtering is a positional relationship in which sputtering particles incident at an angle formed of 50° or less with respect to a normal to a sloping wall of the V-groove are incident on said V-groove formed in said placed substrate.

14. The film forming method according to claim 13, wherein during said sputtering, said sputtering target support surface is fixed and said shield plate and said substrate support surface are rotated.

15. The film forming method according to claim 14, wherein said stage includes a substrate placing table rotatable about a third rotating shaft perpendicular to said second rotating shaft, and
said substrate placing table is rotated 180° about said third rotating shaft when film forming of a region on which a film is to be formed on said substrate is finished during said sputtering.

16. The film forming method according to claim 13, wherein said sputtering target support surface and said substrate support surface are rotated in the same direction and in parallel with each other during said sputtering.

17. The film forming method according to claim 16, wherein said stage includes a substrate placing table rotatable about a third rotating shaft perpendicular to said second rotating shaft, and
said substrate placing table is rotated 180° about said third rotating shaft when film forming of a region on which a film is to be formed on said substrate is finished during said sputtering.

18. A sputtering apparatus comprising:
a cathode having a sputtering target support surface rotatable about a first rotating shaft;
a stage having a substrate support surface rotatable about a second rotating shaft arranged in parallel with said first rotating shaft; and
a shield plate provided between said sputtering support surface and said substrate support surface and rotatable about said first rotating shaft or said second rotating shaft,
wherein said shield plate has a slit-shaped opening portion through which sputtering particles can pass,
said opening portion has a larger width in a direction perpendicular to a rotational direction of said shield plate than a width in said rotational direction,
at least one V-groove is formed in a substrate placed on said substrate support surface, and
the substrate is placed on the substrate support surface so that a longitudinal direction of said V-groove formed in the substrate matches the direction perpendicular to the rotational direction of said shield plate.

19. The sputtering apparatus according to claim 18, wherein rotation of at least one of said sputtering target support surface, said substrate support surface, and said shield plate is controlled during sputtering so that a positional relationship between said sputtering target support surface, said substrate support surface, and said shield plate during said sputtering is a positional relationship in which sputtering particles incident at an angle formed 50° or less with respect to a normal to a sloping wall of the V-groove are incident on said V-groove formed in said placed substrate.

20. A film forming method using a sputtering apparatus comprising:
a cathode having a sputtering target support surface rotatable about a first rotating shaft;
a stage having a substrate support surface rotatable about a second rotating shaft arranged in parallel with said first rotating shaft; and
a shield plate provided between said sputtering support surface and said substrate support surface and rotatable about said first rotating shaft or said second rotating shaft,
wherein said shield plate has a slit-shaped opening portion through which sputtering particles can pass,
said opening portion has a larger width in a direction perpendicular to a rotational direction of said shield plate than a width in said rotational direction,
at least one V-groove is formed in a substrate placed on said substrate support surface, and
the substrate is placed on the substrate support surface so that a longitudinal direction of said V-groove formed in the substrate matches the direction perpendicular to the rotational direction of said shield plate.

21. The film forming method according to claim 20, wherein at least one of said sputtering target support surface, said substrate support surface, and said shield plate is rotated during sputtering so that a positional relationship between said sputtering target support surface, said substrate support surface, and said shield plate during said sputtering is a positional relationship in which sputtering particles incident at an angle formed of 50° or less with respect to a normal to a sloping wall of the V-groove are incident on said V-groove formed in said placed substrate.
